(19) United States
(12) Patent Application Publication
(10) Pub. No.: US 2009/0272975 A1
(43) Pub. Date: Nov. 5, 2009

(54) Poly-Crystalline Layer Structure for Light-Emitting Diodes

(76) Inventors: Ding-Yuan Chen, Taichung (TW); Wen-Chih Chiou, Miaoli (TW); Chia-Lin Yu, Sigang (TW); Chen-Hua Yu, Hsin-Chu (TW)

Correspondence Address: SLATER & MATSIL, L.L.P., 17950 PRESTON ROAD, SUITE 1000, DALLAS, TX, 75252, US

(21) Appl. No.: 12/189,558

(22) Filed: Aug. 11, 2008

Related U.S. Application Data
(60) Provisional application No. 61/050,485, filed on May 5, 2008.

(51) Int. Cl. H01L 33/00

(52) U.S. Cl. 257/51; 257/E33.023

(57) ABSTRACT

A structure and method for a light-emitting diode are presented. A preferred embodiment comprises a substrate with a conductive, poly-crystalline, silicon-containing layer over the substrate. A first contact layer is epitaxially grown, using the conductive, poly-crystalline, silicon-containing layer as a nucleation layer. An active layer is formed over the first contact layer, and a second contact layer is formed over the active layer.

This application claims the benefit of U.S. Provisional Application No. 61/050,485, filed on May 5, 2008, entitled “Method of Using Poly-crystalline Conductive Si-containing Material as Nucleation Layer(s) and Related Semiconductor Devices,” which application is hereby incorporated herein by reference.

### TECHNICAL FIELD

The present invention relates generally to a system and method of forming light-emitting diodes (LEDs) and, more particularly, to a system and method for forming an LED with a poly-crystalline, silicon-containing material as a nucleation layer.

### BACKGROUND

Generally, LEDs are manufactured by forming active regions on a substrate and by depositing various conductive and semiconductive layers on the substrate. The radiative recombination of electron-hole pairs can be used for the generation of electromagnetic radiation by the electric current in a p-n junction. In a forward-biased p-n junction fabricated from a direct band gap material, such as GaAs or GaN, the recombination of the electron-hole pairs injected into the depletion region causes the emission of electromagnetic radiation. The electromagnetic radiation may be in the visible range or may be in a non-visible range. Different colors of LEDs may be created by using materials with different band gaps. Further, an LED with electromagnetic radiation emitting in a non-visible range may direct the non-visible light towards a phosphor lens or a like material type. When the non-visible light is absorbed by the phosphor, the phosphor emits a visible light.

The active regions of the LED are typically formed on the substrate by forming a low temperature non-conductive amorphous film on the substrate, and then using this film as a nucleation layer to grow a first epitaxial contact layer, an active layer, and a second epitaxial layer. However, by using a low temperature amorphous material, more time is needed to grow the low temperature amorphous material, which increases the cost of epitaxial growth.

As such, what is needed is a different layer on which to epitaxially grow the LED elements that is quicker and more cost effective.

### SUMMARY OF THE INVENTION

These and other problems are generally solved or circumvented, and technical advantages are generally achieved, by preferred embodiments of the present invention which provides light-emitting diodes (LEDs) with a poly-crystalline layer used as a nucleation layer.

In accordance with a preferred embodiment of the present invention, a light-emitting diode comprises a substrate and a poly-crystalline, silicon-containing layer over the substrate. A first contact layer is over the poly-crystalline, silicon-containing layer, an active layer is over the first contact epitaxial layer, and a second contact layer is over the active layer.

In accordance with another preferred embodiment of the present invention, a light-emitting diode comprises a substrate and a first layer over the substrate, wherein the first layer comprises a conductive poly-crystalline material with a first crystalline structure. A first contact layer is over the first layer and comprises the first crystalline structure. An active layer is over the first contact layer and a second contact layer is over the active layer.

In accordance with yet another preferred embodiment of the present invention, a method for forming a light-emitting diode comprises providing a substrate and forming a poly-crystalline, silicon-containing layer over the substrate. A first contact layer is epitaxially grown over the poly-crystalline, silicon-containing layer, an active layer is formed over the first contact layer, and a second contact layer is epitaxially grown over the active layer.

An advantage of a preferred embodiment of the present invention is a decrease in the cost of the epitaxial growth and a reduction in the time required to form the nucleation layers. Additionally, the poly-crystalline layer is more suitable for vertical chip fabrication.

### BRIEF DESCRIPTION OF THE DRAWINGS

For a more complete understanding of the present invention, and the advantages thereof, reference is now made to the following descriptions taken in conjunction with the accompanying drawing, in which:

FIG. 1 illustrates a substrate and a poly-crystalline layer over the substrate in accordance with an embodiment of the present invention;

FIG. 2 illustrates the formation of a first contact layer over the poly-crystalline layer in accordance with an embodiment of the present invention;

FIG. 3 illustrates the formation of an active layer over the first contact layer in accordance with an embodiment of the present invention; and

FIG. 4 illustrates the formation of a second contact layer over the active layer in accordance with an embodiment of the present invention.

Corresponding numerals and symbols in the different figures generally refer to corresponding parts unless otherwise indicated. The figures are drawn to clearly illustrate the relevant aspects of the preferred embodiments and are not necessarily drawn to scale.

### DETAILED DESCRIPTION OF ILLUSTRATIVE EMBODIMENTS

The making and using of the presently preferred embodiments are discussed in detail below. It should be appreciated, however, that the present invention provides many applicable inventive concepts that can be embodied in a wide variety of specific contexts. The specific embodiments discussed are merely illustrative of specific ways to make and use the invention, and do not limit the scope of the invention.

The present invention will be described with respect to preferred embodiments in a specific context, namely a light-emitting diode. The invention may also be applied, however, to other epitaxially grown layers.

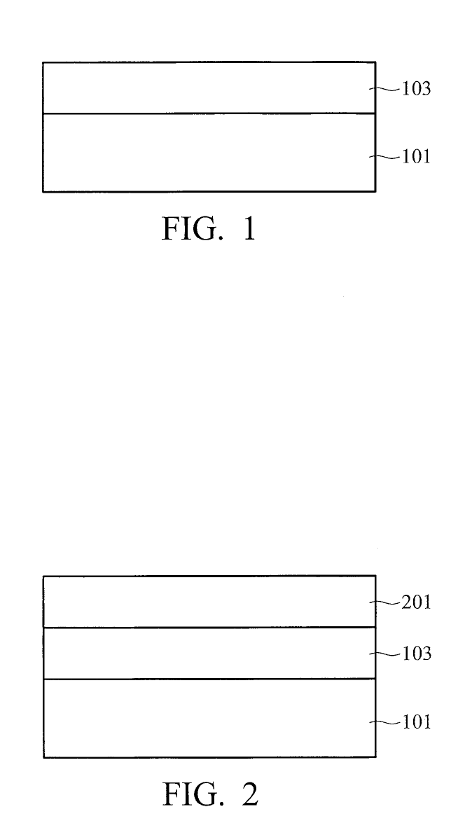

With reference now to FIG. 1, there is shown a substrate 101 with a poly-crystalline layer 103 over the substrate 101. Substrate 101 preferably comprises a non-conductive substrate such as undoped silicon, sapphire, MgAl₂O₄, oxide monocrystalline, combinations of these, or the like. Alternatively, a conductive substrate doped to a desired conductivity, such as GaN, Si, Ge, SiC, SiGe, ZnO, ZnS, ZnSe, GaP, GaAs, combinations of these, or the like, may be used.

A poly-crystalline layer 103 is preferably formed over the substrate 101. The poly-crystalline layer 103 preferably comprises a poly-crystalline, silicon-containing material, such as polysilicon, Si₁₋ₓGeₓ, or Si₁₋ₓCₓ. The poly-crystalline layer 103 is preferably formed through an epitaxial process such as molecular beam epitaxy (MBE), hydride vapor phase epitaxy (HVPE), liquid phase epitaxy (LPE), or the like, although other processes, such as chemical vapor deposition (CVD), physical vapor deposition (PVD), or low-pressure chemical vapor deposition (LPCVD), may alternatively be used.

Preferably, the poly-crystalline layer 103 is doped with a dopant to make it conductive. In an embodiment in which a p-up LED is being fabricated, the poly-crystalline layer 103 is preferably doped with an n-type dopant, such as phosphorous, arsenic, antimony, and the like. However, p-type dopants may alternatively be used, depending upon the desired conductivity of the poly-crystalline layer 103 to form an n-up LED. The dopants are preferably introduced as a precursor during the formation of the poly-crystalline layer 103. However, other suitable methods for doping the poly-crystalline layer 103, such as ion implantation, ion diffusion, combinations of these, and the like, may alternatively be used. The poly-crystalline layer 103 preferably has a dopant concentration of between about 1×10¹⁵ cm⁻³ and about 1×10¹⁹ cm⁻³, with a preferred dopant concentration of about 5×10¹⁶ cm³. By making the poly-crystalline layer 103 conductive, the poly-crystalline layer 103 may be used in the fabrication of a vertical chip.

The poly-crystalline layer 103 is preferably formed to a thickness of between about 5 nm and about 100 nm, with a preferred thickness of about 30 nm. This thickness is preferably achieved by forming the poly-crystalline layer 103 with chemical vapor deposition using such chemical precursors as SiH₄, GeH₄, or CH₄ with a pressure of between about 1 torr and about 760 torr, with a preferred pressure of about 10 torr, and a temperature of between about 300° C. and about 800° C., with a preferred temperature of about 600° C.

FIG. 2 illustrates the formation of a first contact layer 201 over the poly-crystalline layer 103, using the poly-crystalline layer 103 as a nucleation layer. The first contact layer 201 preferably forms one part of the diode required to emit light, and preferably comprises a group III-V compound. As the name implies, group III-V compounds comprise a group III element and a group V element and include compounds such as GaN, InN, AlN, AlₓGa(₁₋ₓ₎N, AlₓIn₍₁₋ₓ₎N, AlₓIn_{y}Ga_{(1-x-y)}N, combinations thereof, or the like, doped with a dopant of a first conductivity type (e.g., n-GaN).

The first contact layer 201 is preferably formed, for example, through an epitaxial growth process such metal organic chemical vapor deposition (MOCVD) using the poly-crystalline layer 103 as a nucleation layer, thereby continuing the crystalline structure of the poly-crystalline layer 103 to the first contact layer 201. Other processes, however, such as MBE, HVPE, LPE, or the like, may alternatively be utilized. The first contact layer 201 is preferably formed to have a thickness of between about 1 μm and about 6 μm, with a preferred thickness of about 2 μm. The first contact layer 201 is preferably doped in situ during formation to a concentration of between about 1×10¹⁶ cm⁻³ and about 1×10¹⁹ cm⁻³, with a preferred dopant concentration of about 1×10¹⁸ cm⁻³, although other processes, such as ion implantation or diffusion may alternatively be utilized.

By using the poly-crystalline layer 103 as a nucleation layer for the growth of the first contact layer 201, a higher temperature growth can be utilized. Additionally, less time is required to grow the first contact layer 201 and associated costs with epitaxy are reduced.

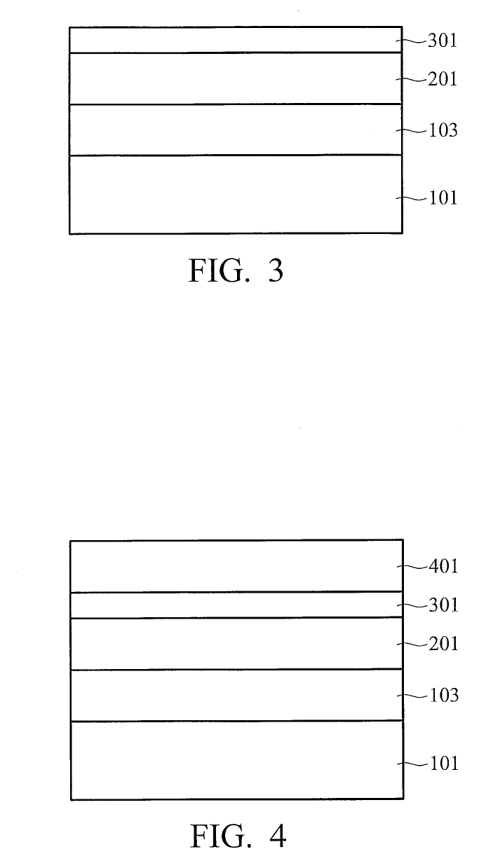

FIG. 3 illustrates the formation of an active layer 301 over the first contact layer 201. The active layer 301 is designed, among other things, to control the generation of light to desired wavelengths. For example, by adjusting and controlling the proportional composition of the elements in the active layer 301, the bandgap of the materials in active layer 301 may be adjusted, thereby adjusting the wavelength of light that will be emitted by the LED.

Active layer 301 preferably comprises multiple quantum wells (MQW). MQW structures in active layer 301 may comprise, for example, layers of InGaN, GaN, AₓIn_{y}Ga_{(1-x-y)}N (where (0<=x<=1)), or the like. Active layer 301 may comprise any number of quantum wells, 3 or 5 quantum wells for example, each preferably about 30 to about 100 Å thick. The MQW are preferably epitaxially grown using the first contact layer 201 as a buffer layer using metal organic chemical vapor deposition (MOCVD), although other processes, such as MBE, HVPE, LPE, or the like, may alternatively be utilized.

FIG. 4 illustrates the formation of a second contact layer 401 over the active layer 301. The second contact layer 401 preferably forms the second part of the diode required to emit light in conjunction with the first contact layer 201. The second contact layer 401 preferably comprises a group III-V compound such as GaN, InN, AlN, AlₓGa₍₁₋ₓ₎N, AlₓIn₍₁₋ₓ₎N, AlₓIn_{y}Ga_{(1-x-y)}N, combinations thereof, or the like, doped with a dopant of a second conductivity type (e.g., p-GaN) opposite the first conductivity type in the first contact layer 201.

The second contact layer 401 is preferably formed, for example, through an epitaxial growth process such as MOCVD. Other processes, however, such as HVPE, LPE, MBE, or the like, may alternatively be utilized. The second contact layer 401 is preferably formed to have a thickness of between about 0.1 μm and about 2 μm, with a preferred thickness of about 0.3 μm and is preferably doped in situ to a concentration of between about 1×10¹⁷ cm⁻³and about 1×10²¹ cm⁻³, with a preferred dopant concentration of about 1×10¹⁹ cm⁻³, although other processes, such as ion implantation or diffusion may alternatively be utilized.

As one of ordinary skill in the art will recognize, the above described embodiment in which a light-emitting diode is formed with an n-type conductivity in the first contact layer 201 and a p-type conductivity in the second contact layer 401 is but a single potential embodiment of the present invention. Alternatively, a light-emitting diode may be formed using a p-type conductivity in the first contact layer 201 and an n-type conductivity in the second contact layer 401. The present invention may be utilized with any combination of p-type and n-type conductivities, and these combinations are fully intended to be included within the scope of the present invention.

Thereafter, processes may be performed to complete the LED device. For example, electrical contacts (front-side and/or back-side contacts) may be formed to the first and second contact layers 201 and 401, respectively, passivation layers may be formed, and the LED device may be diced and packaged.

It should also be noted that the above description describes a method of forming LED devices using a poly-crystalline layer. Other layers, such as a distributed Bragg reflector, may be desirable in addition to the poly-crystalline layer. A distributed Bragg reflector generally comprises multiple layers having different refractive indices that causes light emitted from the LED structures to be reflected, thereby increasing the light emitted from the top of the LED device. A reflective buffer layer may also be used with or in place of the distributed Bragg reflector.

The structure of the LED structure may also vary depending on the type of materials used and the intended application. It is expected that the many types of LED structures may be used with embodiments of the present invention, which provide a conductive, silicon-containing crystalline structure to form an LED structure.

Although the present invention and its advantages have been described in detail, it should be understood that various changes, substitutions and alterations can be made herein without departing from the spirit and scope of the invention as defined by the appended claims. For example, many of the features and functions discussed above can be implemented using different materials or methods while remaining within the scope of the present invention.

Moreover, the scope of the present application is not intended to be limited to the particular embodiments of the process, machine, manufacture, composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

What is claimed is:

1. A light-emitting diode comprising:
a substrate;
a poly-crystalline layer over the substrate, the poly-crystalline layer comprising silicon;
a first contact layer on the poly-crystalline, silicon-containing layer;
an active layer over the first contact layer; and
a second contact layer over the active layer.

2. The light-emitting diode of claim 1, wherein the poly-crystalline layer comprises polysilicon.

3. The light-emitting diode of claim 1, wherein the poly-crystalline layer is conductive.

4. The light-emitting diode of claim 1, wherein the first contact layer comprises a group III-nitride.

5. The light-emitting diode of claim 1, wherein the poly-crystalline layer comprises Si₁₋ₓGeₓ.

6. The light-emitting diode of claim 1, wherein the substrate comprises silicon.

7. The light-emitting diode of claim 1, wherein the substrate comprises a conductive material.

8. The light-emitting diode of claim 1, wherein the substrate comprises a non-conductive material.

9. A light-emitting diode comprising:
a substrate;
a first layer over the substrate, the first layer comprising a conductive poly-crystalline material;
a first contact layer over the first layer;
an active layer over the first contact layer; and
a second contact layer over the active layer.

10. The light-emitting diode of claim 9, wherein the conductive poly-crystalline material comprises silicon.

11. The light-emitting diode of claim 9, wherein the first layer comprises polysilicon.

12. The light-emitting diode of claim 9, wherein the first contact layer comprises a group III-nitride.

13. The light-emitting diode of claim 9, wherein the substrate comprises a conductive material.

14. The light-emitting diode of claim 9, wherein the substrate comprises a non-conductive material.

15. A light-emitting diode comprising:
a substrate;
a poly-crystalline layer over the substrate, the poly-crystalline layer being conductive and comprising a silicon-containing material;
a first contact layer on the poly-crystalline layer;
an active layer over the first contact layer; and
a second contact layer over the active layer.

16. The light-emitting diode of claim 15, wherein the poly-crystalline layer comprises polysilicon.

17. The light-emitting diode of claim 15, wherein the first contact layer comprises a group III-nitride.

18. The light-emitting diode of claim 15, wherein the substrate comprises a conductive material.

19. The light-emitting diode of claim 15, wherein the substrate comprises a nonconductive material.

20. The light-emitting diode of claim 15, wherein the poly-crystalline layer comprises Si₁₋ₓGeₓ.
